(19) United States
(12) Patent Application Publication
(10) Pub. No.: US 2025/0201742 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventors: Takashi TONEGAWA, Tokyo (JP); Yuji ENARI, Tokyo (JP); Shota OKABE, Tokyo (JP)

(21) Appl. No.: 18/951,788

(22) Filed: Nov. 19, 2024

(30) Foreign Application Priority Data
Dec. 15, 2023 (JP) 2023-212395

(51) Int. Cl. H01L 23/00; C23C 18/16; C23C 18/32; C23C 18/44

(52) U.S. Cl. CPC H01L 24/05; C23C 18/1651; C23C 18/32; C23C 18/44; H01L 24/03; H01L 2224/03462; H01L 2224/05124; H01L 2224/05155; H01L 2224/05582; H01L 2224/05644

(57) ABSTRACT

A pad is formed on an interlayer insulating film, and an insulating film is formed to cover the interlayer insulating film and the pad. An opening is formed in the insulating film to expose a part of the pad. In the opening, a nickel plating film is formed on the pad, a first gold plating film is formed on the nickel plating film, and a second gold plating film is formed on the first gold plating film. A phosphorus concentration of the nickel plating film is 2% by mass or more and 7% by mass or less.

### CROSS-REFERENCE TO RELATED APPLICATION

The disclosure of Japanese Patent Application No. 2023-212395 filed on Dec. 15, 2023, including the specification, drawings and abstract is incorporated herein by reference in its entirety.

### BACKGROUND

The present invention relates to a semiconductor device and a method of manufacturing the same, and is suitably applicable to, for example, a semiconductor device including an electrode pad and a method of manufacturing the same.

There is disclosed a technique listed below.
[Patent Document 1] Japanese Unexamined Patent Application Publication No. 2020-120133

An OPM (over pad metal) film is formed on an electrode pad in a semiconductor device. The Patent Document 1 discloses a technique using a stacked film of a nickel plating layer and a gold plating layer as an OPM film.

In a semiconductor device including a pad and an OPM film, it is desired to improve the reliability thereof.

Other problems and novel characteristics will be apparent from the description of this specification and the accompanying drawings.

According to an embodiment, a semiconductor device includes an electrode pad, a nickel plating film formed on the electrode pad in an opening of a passivation film, a first gold plating film formed on the nickel plating film, and a second gold plating film formed on the first gold plating film. A phosphorus concentration of the nickel plating film is 2% by mass or more and 7% by mass or less.

According to the embodiment, the reliability of the semiconductor device can be improved.

### BRIEF DESCRIPTIONS OF THE DRAWINGS

FIG. 1 is a top view of a semiconductor device according to a first embodiment;

FIG. 2 is a back view of the semiconductor device according to the first embodiment;

FIG. 3 is a cross-sectional view of a principal part of the semiconductor device according to the first embodiment;

FIG. 4 is a cross-sectional view of a principal part of the semiconductor device according to the first embodiment;

FIG. 5 is a cross-sectional view of a principal part during a step of manufacturing the semiconductor device according to the first embodiment;

FIG. 6 is a cross-sectional view of a principal part during a step of manufacturing the semiconductor device, continued from the step illustrated in FIG. 5;

FIG. 7 is a cross-sectional view of a principal part during a step of manufacturing the semiconductor device, continued from the step illustrated in FIG. 6;

FIG. 8 is a cross-sectional view of a principal part during a step of manufacturing the semiconductor device, continued from the step illustrated in FIG. 7;

FIG. 9 is a cross-sectional view of a principal part during the same step of manufacturing the semiconductor device, as the step illustrated in FIG. 8;

FIG. 10 is a cross-sectional view a principal part during a step of manufacturing the semiconductor device, continued from the step illustrated in FIG. 8;

FIG. 11 is a cross-sectional view of a principal part during the same step of manufacturing the semiconductor device, as the step illustrated in FIG. 10;

FIG. 12 is a cross-sectional view of a principal part during a step of manufacturing the semiconductor device, continued from the step illustrated in FIG. 10;

FIG. 13 is a cross-sectional view of a principal part during the same step of manufacturing the semiconductor device, as the step illustrated in FIG. 12;

FIG. 14 is a cross-sectional view of a principal part during a step of manufacturing the semiconductor device, continued from the step illustrated in FIG. 12;

FIG. 15 is a cross-sectional view of a principal part during the same step of manufacturing the semiconductor device, as the step illustrated in FIG. 14;

FIG. 16 is an explanatory diagram of a displacement reaction occurring in displacement Au plating process;

FIG. 17 is a cross-sectional view of a principal part during a step of manufacturing the semiconductor device, continued from the step illustrated in FIG. 14;

FIG. 18 is a cross-sectional view of a principal part during the same step of manufacturing the semiconductor device, as the step illustrated in FIG. 17;

FIG. 19 is a cross-sectional view of a semiconductor package according to the first embodiment;

FIG. 20 is a cross-sectional view of a principal part of a semiconductor device in a first examination example;

FIG. 21 is a cross-sectional view of a principal part of the semiconductor device in the first examination example;

FIG. 22 is a cross-sectional view of a principal part during a step of manufacturing a semiconductor device in a second examination example;

FIG. 23 is a cross-sectional view of a principal part of a step of manufacturing the semiconductor device, continued from the step illustrated in FIG. 22;

FIG. 24 is a cross-sectional view of a principal part of a semiconductor device in a third examination example;

FIG. 25 is a cross-sectional view of a principal part of the semiconductor device according to the first embodiment;

FIG. 26 is a graph illustrating a correlation between the thickness of a low density layer formed in a surface layer part of a nickel plating film and the phosphorus concentration of the nickel plating film at the time of displacement Au plating process;

FIG. 27 is a table illustrating a correlation between the phosphorus concentration of the nickel plating film and the heat resistance of the nickel plating film;

FIG. 28 is a cross-sectional view of a principal part during a step of manufacturing a semiconductor device according to a second embodiment; and

FIG. 29 is a cross-sectional view of a principal part during a step of manufacturing the semiconductor device, continued from the step illustrated in FIG. 28.

### SUMMARY

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference symbols throughout the drawings for describing the embodiment, and the repetitive description thereof will be omitted. In addition, the description of the same or similar portions is not repeated in principle unless otherwise particularly required in the following embodiments.

Also, in some drawings used in the embodiments, hatching may be omitted even in a cross-sectional view so as to make the drawings easy to see. The hatching may be added even in a plan view so as to make the drawings easy to see.

### First Embodiment

### <Structure of Semiconductor Device>

A semiconductor device according to an embodiment will be described with reference to the drawings.

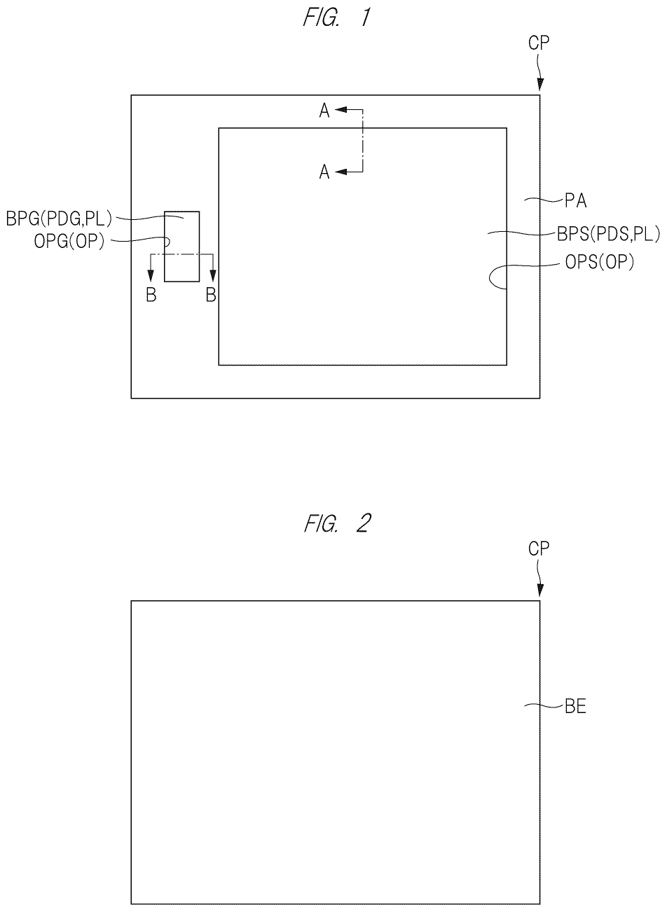

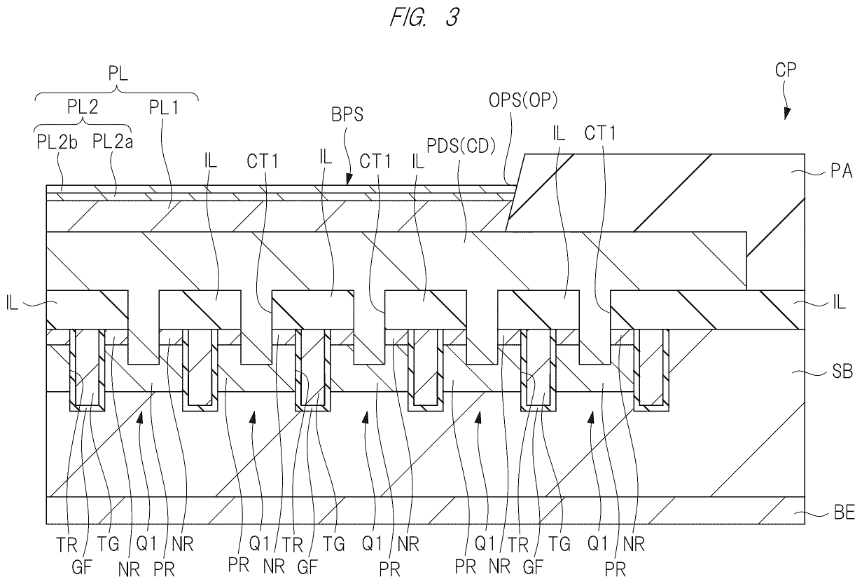

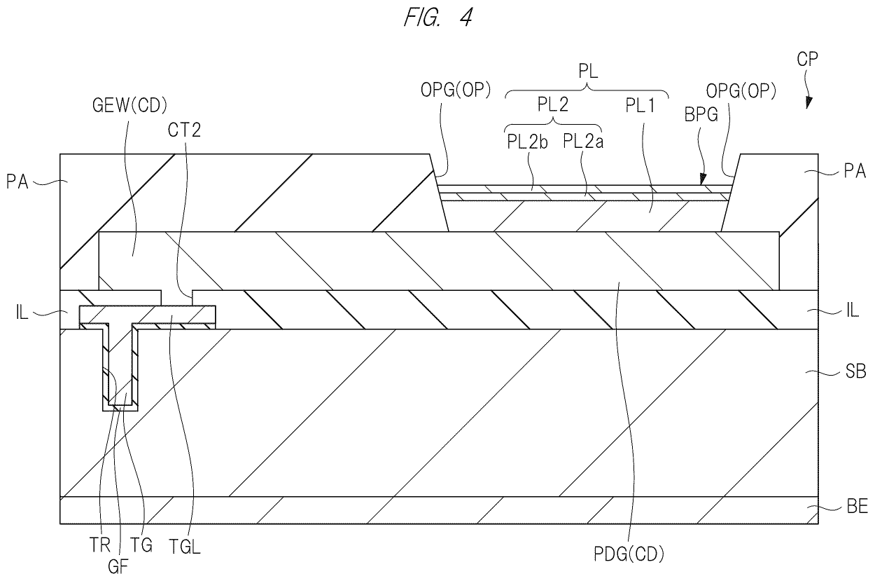

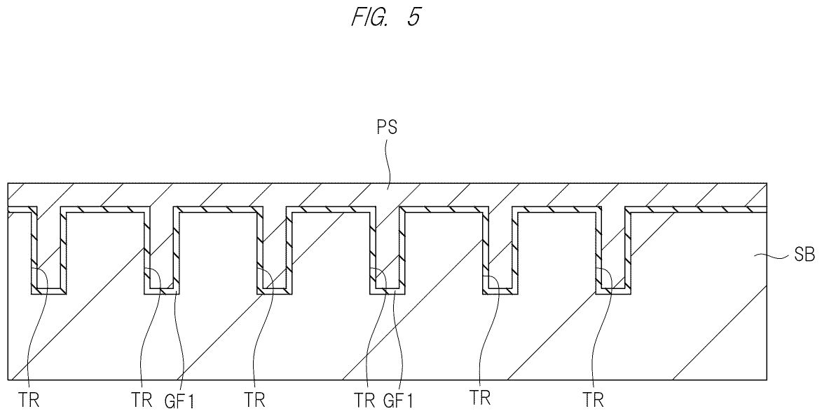

FIG. 1 is a top view of a semiconductor device CP according to the present embodiment. FIG. 2 is a back view of the semiconductor device CP according to the present embodiment. Each of FIGS. 3 and 4 is a cross-sectional view of a principal part of the semiconductor device CP according to the present embodiment. A cross-sectional view taken along a line A-A illustrated in FIG. 1 almost corresponds to FIG. 3, and a cross-sectional view taken along a line B-B illustrated in FIG. 1 almost corresponds to FIG. 4.

As illustrated in FIGS. 1 to 4, the semiconductor device CP according to the present embodiment includes a semiconductor substrate SB, an interlayer insulating film IL, a back surface electrode BE, a source pad PDS, a gate pad PDG, a gate wiring part GEW, an insulating film PA, and a plating film PL. The semiconductor device CP further includes a trench gate electrode TG, an n-type semiconductor region NR formed in the semiconductor substrate SB, and a p-type semiconductor region PR formed in the semiconductor substrate SB.

The semiconductor substrate SB is made of, for example, n-type single crystal silicon doped with an n-type impurity such as arsenic (As). A semiconductor substrate (so-called epitaxial wafer) including a substrate main body made of an n-type single crystal silicon substrate and an epitaxial layer made of n-type single crystal silicon formed on the substrate main body can also be used as the semiconductor substrate SB.

The semiconductor substrate SB has a main surface and a back surface opposite to the main surface. The interlayer insulating film IL is formed on the main surface of the semiconductor substrate SB, and the back surface electrode BE is formed on the back surface of the semiconductor substrate SB.

In the semiconductor substrate SB, a trench gate type MISFET (metal-insulator-semiconductor field effect transistor) is formed. The trench gate type MISFET has a trench type gate structure. The trench type gate structure corresponds to a gate electrode structure embedded in a trench formed in a substrate.

A specific configuration of the trench gate type MISFET formed in the semiconductor substrate SB will be described below. The trench gate type MISFET forming a power transistor (power semiconductor element) is formed on the main surface of the semiconductor substrate SB. Specifically, a plurality of unit transistor cells Q1 are formed on the main surface of the semiconductor substrate SB. The plurality of unit transistor cells Q1 formed on the semiconductor substrate SB are connected in parallel, thereby forming one power transistor. Each of the unit transistor cells Q1 is made of the trench gate type MISFET. Here, a planar region where the plurality of unit transistor cells Q1 forming the power transistor are formed on the main surface of the semiconductor substrate SB is referred to as a transistor cell region.

The semiconductor substrate SB has a function serving as a drain region of each of the unit transistor cells Q1. The back surface electrode BE for drain is formed on the back surface of the semiconductor substrate SB. The back surface electrode BE is formed on the entire back surface of the semiconductor substrate SB. The back surface electrode BE functions as a drain terminal. The back surface electrode BE is made of, for example, a stacked film of a titanium (Ti) film being in contact with the semiconductor substrate SB, a nickel (Ni) film on the titanium film, and a gold (Au) film or a silver (Ag) film on the nickel film.

The p-type semiconductor region PR is formed in the semiconductor substrate SB in the transistor cell region. The p-type semiconductor region PR has a function serving as a channel formation region of each of the unit transistor cells Q1. In the semiconductor substrate SB, the n-type semiconductor region (source region) NR is formed on the p-type semiconductor region PR. The n-type semiconductor region NR has a function serving as a source region of each of the unit transistor cells Q1. The p-type semiconductor substrate PR exists under the n-type semiconductor region NR. The conductivity of the semiconductor substrate SB interposed between the p-type semiconductor region PR and the back surface electrode BE remains kept as the n-conductivity type, and the semiconductor substrate SB has a function serving as the drain region of each of the unit transistor cells Q1.

A trench (groove) TR is formed in the main surface of the semiconductor substrate SB, and a trench gate electrode TG is embedded in the trench TR through a gate insulating film GF. The trench gate electrode TG is made of a conductor film such as a embedded in the trench TR of the doped polysilicon semiconductor substrate SB. The gate insulating film GF is formed on a bottom surface and a side surface of the trench TR. The gate insulating film GF is made of, for example, a silicon oxide film. Although not illustrated, the trench TR is formed to have, for example, a stripe pattern or a grid pattern on the main surface of the semiconductor substrate SB in plan view.

Description for the plan view of components of the semiconductor device CP corresponds to a case of viewing of a plane substantially parallel to the main surface of the semiconductor substrate SB forming the semiconductor device CP.

The trench TR is formed to penetrate the n-type semiconductor region NR and the p-type semiconductor region PR from the main surface of the semiconductor substrate SB. The bottom surface of the trench TR is deeper than a bottom surface of the n-type semiconductor region NR, and is deeper than a bottom surface of the p-type semiconductor region PR.

Then, a structure of layers upper than the semiconductor substrate SB will be described.

The interlayer insulating film IL is formed on the main surface of the semiconductor substrate SB to cover the trench gate electrode TG. The interlayer insulating films IL is made of a silicon oxide film, for example.

The trench gate electrodes TG in the plurality of unit transistor cells Q1 are integrally connected to one another in a region not illustrated in cross-sectional views of FIGS. 3 and 4. A gate lead-out part TGL formed integrally with each of the trench gate electrodes TG is formed over the main surface of the semiconductor substrate SB outside the trench TR through the gate insulating film GF (see FIG. 4).

Contact holes CT1 and CT2 are formed in the interlayer insulating film IL. The contact hole CT1 is a contact hole for source. The contact hole CT1 is arranged between the adjacent trenches TR in plan view.

The contact hole CT2 is a contact hole for gate. The contact hole CT2 is arranged on the gate lead-out part TGL. A part of the gate lead-out part TGL is exposed from the contact hole CT2.

A source pad (source electrode pad) PDS, a gate pad (gate electrode pad) PDG, and a gate wiring part GEW are formed on the interlayer insulating film IL. The source pad PDS, the gate pad PDG, and the gate wiring part GEW are each made of a patterned conductor film CD. The conductor film CD is made of a metal film mainly containing aluminum (Al), more specifically, made of an aluminum film or an aluminum alloy film.

The gate pad PDG and the gate wiring part GEW are integrally formed. Accordingly, the gate pad PDG and the gate wiring part GEW are electrically connected to each other. The source pad PDS is separated from the gate pad PDG and the gate wiring part GEW.

A part of the source pad PDS is embedded in the contact hole CT1 for source. A portion of the source pad PDS, the portion being embedded in the contact hole CT1 for source, is referred to as a via portion for source.

A part of the gate wiring part GEW is embedded in the contact hole CT2 for gate. A portion of the gate wiring part GEW, the portion being embedded in the contact hole CT2 for gate, is referred to as a via portion for gate.

The via portion for gate is electrically connected to the gate lead-out part TGL while being in contact therewith. The gate pad PDG is electrically connected to the trench gate electrode TG in each of the plurality of unit transistor cells Q1 through the gate wiring part GEW, the via portion for gate, and the gate lead-out part TGL.

The source pad PDS is formed to cover the transistor cell region in plan view.

The contact hole CT1 for source penetrates the interlayer insulating film IL and the n-type semiconductor region NR, to reach the p-type semiconductor region PR. Accordingly, the via portion for source embedded in the contact hole CT1 for source penetrates the interlayer insulating film IL and the n-type semiconductor region NR, to reach the p-type semiconductor region PR. The via portion for source is in contact with both the n-type semiconductor region NR and the p-type semiconductor region PR, and is thus electrically connected to both the n-type semiconductor region NR and the p-type semiconductor region PR.

The source regions (n-type semiconductor regions NR) and the channel formation regions (p-type semiconductor regions PR) in the plurality of unit transistor cells Q1 arranged in the transistor cell region are electrically connected to the common source pad PDS, respectively, through the plurality of via portions for source. In this case, the source pad PDS serves as a source wiring that electrically connects the source regions (n-type semiconductor regions NR) in the plurality of unit transistor cells Q1 to one another. The source wiring that electrically connects the source regions (n-type semiconductor regions NR) in the plurality of unit transistor cells Q1 to one another may be formed on the interlayer insulating film IL, and the source pad PDS may be formed in a layer upper than the source wiring. Similarly, the gate wiring part GEW may be formed on the interlayer insulating film IL, and the gate pad PDG may be formed in a layer upper than the gate wiring part GEW.

An insulating film PA is formed as a passivation film on the interlayer insulating film IL to cover a part of the source pad PDS, a part of the gate pad PDG, and the gate wiring part GEW. The insulating film PA is a protective film in the uppermost layer of the semiconductor device CP. The insulating film PA is made of, for example, a resin film made of polyimide resin or the like.

The insulating film PA has openings OPS and OPG formed therein. At least a part of the source pad PDS is exposed from the opening OPS of the insulating film PA. At least a part of the gate pad PDG is exposed from the opening OPG of the insulating film PA. A plating film PL is formed on each of the source pad PDS exposed from the opening OPS of the insulating film PA and the gate pad PDG exposed from the opening OPG of the insulating film PA.

The plating film PL is an OPM film. An upper surface of the insulating film PA and an upper surface of the plating film PL form an upper surface of the semiconductor device CP. A front surface of the back surface electrode BE forms a back surface of the semiconductor device CP. The gate wiring part GEW is not exposed from the insulating film PA. The entire gate wiring part GEW is covered with the insulating film PA. The plating film PL is not formed on the gate wiring part GEW.

The plating film PL is selectively formed on the source pad PDS exposed from the opening OPS of the insulating film PA and on the gate pad PDG exposed from the opening OPG of the insulating film PA. That is, the plating film PL is formed on the source pad PDS in the opening OPS, and the plating film PL is formed on the gate pad PDG in the opening OPG. The plating film PL is not formed on each of the source pad PDS covered with the insulating film PA and the gate pad PDG covered with the insulating film PA.

The plating film PL is made of a stacked film of a nickel (Ni) plating film PL1 and a gold (Au) plating film PL2 formed on the nickel plating film PL1.

The nickel plating films PL1 are respectively formed on the source pad PDS to be in contact with the source pad PDS in the opening OPS and formed on the gate pad PDG to be in contact with the gate pad PDG in the opening OPG. The gold plating film PL2 is formed on the nickel plating film PL1 to be in contact with the nickel plating film PL1.

The nickel plating film PL1 contains phosphorus (P). The phosphorus (P) concentration of the nickel plating film PL1 is 2% by mass or more and 7% by mass or less, preferably 2% by mass or more and 5.7% by mass or less, and more preferably 2% by mass or more and 4.0% by mass or less. Note that the unit “percent by mass” may be referred to as “percent by weight”.

The gold plating film PL2 is made of a stacked film of a gold (Au) plating film PL2a formed on the nickel plating film PL1 and a gold (Au) plating film PL2b formed on the gold plating film PL2a. The gold plating film PL2a is a displacement gold plating film formed by displacement Au (gold) plating process. The gold plating film PL2b is a reduction gold plating film formed by reduction Au (gold) plating process. The gold plating film PL2a is formed on the nickel plating film PL1 to be in contact with the nickel plating film PL1. The gold plating film PL2b is formed on the gold plating film PL2a to be in contact with the gold plating film PL2a.

Therefore, the plating film PL is made of a stacked film of the nickel plating film PL1, the gold plating film PL2a formed on the nickel plating film PL1, and the gold plating film PL2b formed on the gold plating film PL2a. The gold plating film PL2b is positioned in the uppermost layer of the plating film PL. An upper surface of the gold plating film PL2b forms an upper surface of the plating film PL.

The source pad PDS is formed to cover the transistor cell region in plan view. Accordingly, the area of the source pad PDS is larger than the area of the gate pad PDG. Therefore, an area of the opening OPS is larger than an area of the opening OPG. A planar shape of each of the openings OPG and OPS is, for example, rectangular.

A combined body of the source pad PDS and the plating film PL on the source pad PDS is referred to as a bonding pad for source BPS. A combined body of the gate pad PDG and the plating film PL on the gate pad PDG is referred to as a bonding pad for gate BPG.

The nickel plating film PL1 of the plating film PL, when being solder-connected to the bonding pad, functions as a barrier layer (solder barrier layer) that prevents diffusion of a solder component into the conductor film CD after passing through the plating film PL. The nickel plating film PL1 also has a function of ensuring the bonding strength of the solder. The gold plating film PL2 of the plating film PL is provided to prevent oxidation of the nickel plating film PL1 and to improve the wettability of the solder.

When wire bonding to the bonding pad is performed, the gold plating film PL2 has a function of achieving easiness of the wire connection.

In the semiconductor device CP having such a configuration, an operation current of a power transistor flows between the source pad PDS and the back surface electrode BE for drain. That is, an operation current of the trench gate type MISFET formed in the transistor cell region flows in a thickness direction of the semiconductor substrate SB. Accordingly, the trench gate type MISFET formed in the transistor cell region is a vertical transistor. Here, the vertical transistor corresponds to a transistor, an operation current of which flows in a thickness direction of the semiconductor substrate SB.

In the present embodiment, the case where the trench gate type MISFET is applied as the semiconductor element formed on or in the semiconductor substrate SB has been described. However, the present invention is not limited to this case, but another type of semiconductor element can also be formed on or in the semiconductor substrate SB.

For example, a trench gate type IGBT can also be formed instead of the trench gate type MISFET in the semiconductor substrate SB. If the trench gate type IGBT is applied, a p-type semiconductor substrate region for collector is formed in the vicinity of the back surface of the semiconductor substrate SB. If the trench gate type IGBT is applied, the back surface electrode BE functions as a collector electrode, the n-type semiconductor region NR functions as an n-type semiconductor region for emitter, and the source pad PDS functions as an emitter pad (electrode pad for emitter). The back surface electrode BE is made of, for example, a stacked film of an aluminum silicon alloy (AlSi) film being in contact with the semiconductor substrate SB, a nickel (Ni) film on the aluminum silicon alloy (AlSi) film, and a gold (Au) film or a silver (Ag) film on the nickel film.

An LDMOSFET (laterally diffused metal-oxide-semiconductor field effect transistor) can also be formed instead of the trench gate type MISFET in the semiconductor substrate SB.

The semiconductor device CP can also have a bonding pad other than the bonding pad for source BPS and the bonding pad for gate BPG. In the case, each of the bonding pads is made of a pad (electrode pad) made of the conductor film CD and the plating film PL formed on the pad.

The present embodiment can also be applied to a case where a wiring structure including a plurality of wiring layers (a multilayer wiring structure) is formed on the main surface of the semiconductor substrate SB. In this case, a pad is formed in the uppermost wiring layer among the plurality of wiring layers included in the wiring structure.

### <Steps of Manufacturing Semiconductor Device>

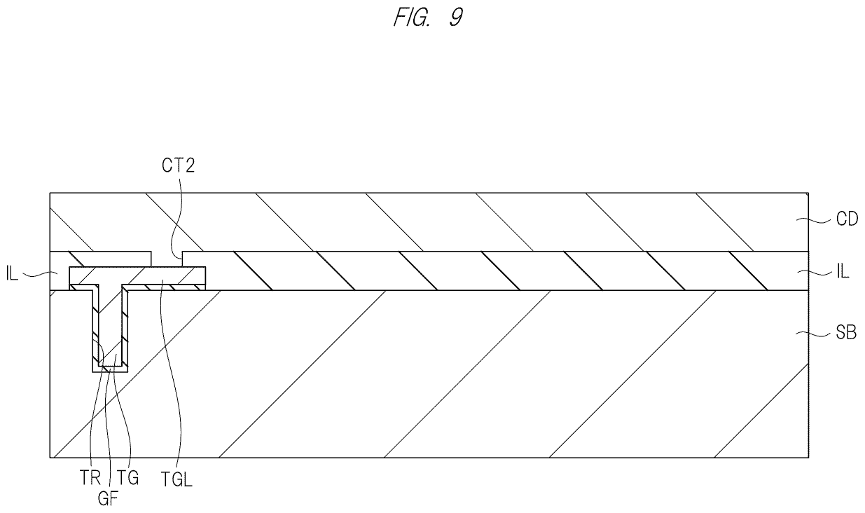

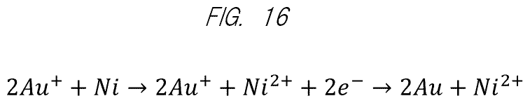

Steps of manufacturing the semiconductor device CP according to the present embodiment will be described with reference to FIGS. 5 to 18. Each of FIGS. 5 to 15, 17, and 18 is a cross-sectional view of a principal part during steps of manufacturing the semiconductor device CP according to the present embodiment. FIG. 16 is an explanatory diagram of the displacement reaction occurring in the displacement Au plating process. Each of FIGS. 5, 6, 7, 8, 10, 12, 14, and 17 illustrates a cross section corresponding to FIG. 3. Each of FIGS. 9, 11, 13, 15, and 18 illustrates a cross section corresponding to FIG. 4.

As illustrated in FIG. 5, the semiconductor substrate SB (semiconductor wafer) made of, for example, an n-type single crystal silicon is prepared. An epitaxial wafer can also be used as the semiconductor substrate SB.

Then, the trench TR is formed on the main surface of the semiconductor substrate SB, as illustrated in FIG. 5. The trench TR can be formed by a photolithography technique and an etching technique.

Then, the gate insulating film GF made of a thin silicon oxide film or the like is formed on a side surface and a bottom surface of the trench TR and the main surface of the semiconductor substrate SB by, for example, a thermal oxidation method.

Then, the conductor film PS made of a polycrystalline silicon film or the like is formed on the main surface of the semiconductor substrate SB to fill the trench TR by a CVD method or the like.

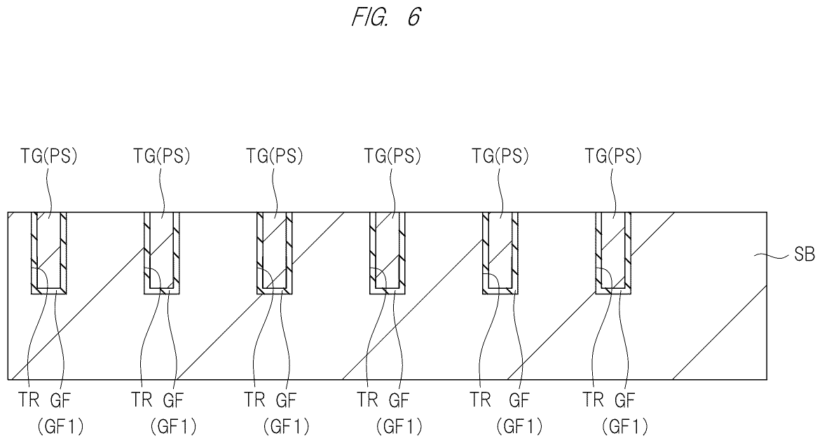

Then, a photoresist pattern (not illustrated) is formed on a part of the conductor film PS, and then the conductor film PS is etched back by an anisotropic etching technique. By the etching back, the conductor film PS is left in the trench TR and under the photoresist pattern, and the other conductor film PS is removed. Then, the photoresist pattern is removed. As a result, the trench gate electrode TG made of the conductor film PS left in the trench TR is formed, as illustrated in FIG. 6. The above-described gate lead-out part TGL is made of the conductor film PS left under the photoresist pattern.

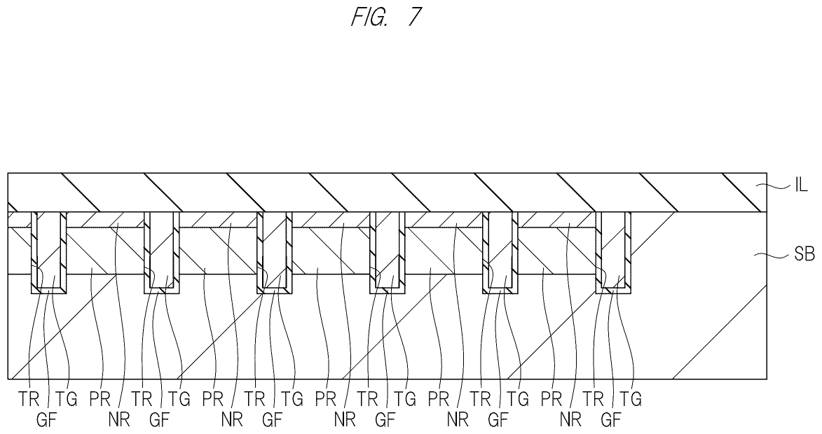

Then, the p-type semiconductor region PR is formed in the semiconductor substrate SB by an ion implantation method, as illustrated in FIG. 7.

Then, the n-type semiconductor region NR is formed in the semiconductor substrate SB by an ion implantation method. A bottom surface of the p-type semiconductor region PR is shallower than a bottom surface of the trench TR. A bottom surface of the n-type semiconductor region NR is shallower than the bottom surface of the p-type semiconductor region PR. Accordingly, the trench TR penetrates the n-type semiconductor region NR and the p-type semiconductor region PR.

Then, the interlayer insulating film IL is formed to cover the trench gate electrode TG and the gate lead-out part TGL on the main surface of the semiconductor substrate SB, as illustrated in FIG. 7.

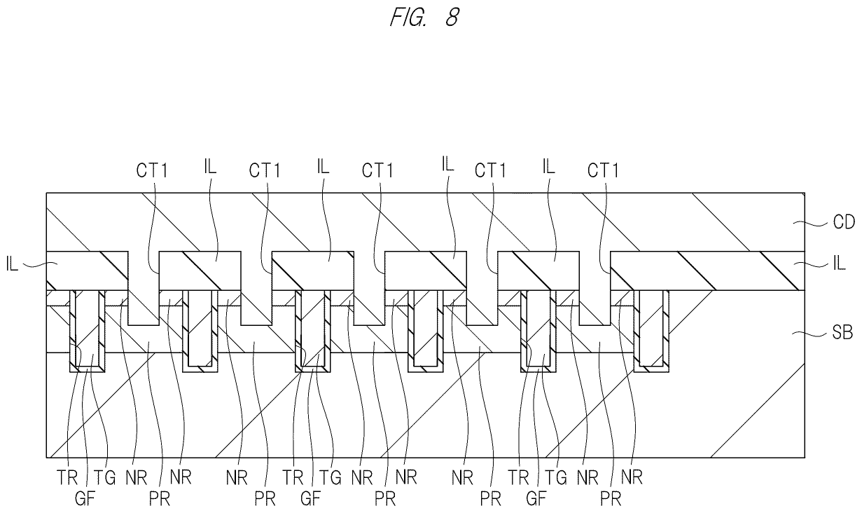

Then, the interlayer insulating film IL and the semiconductor substrate SB are etched while using a photoresist pattern (not illustrated) formed on the interlayer insulating film IL as an etching mask, thereby forming the contact hole CT1 for source, as illustrated in FIG. 8. The p-type semiconductor region PR and the n-type semiconductor region NR are exposed from the contact hole CT1 for source.

Then, the interlayer insulating film IL is etched while using another photoresist pattern (not illustrated) formed on the interlayer insulating film IL as an etching mask, thereby forming the contact hole CT2 for gate, as illustrated in FIG. 9. The gate lead-out part TGL is exposed from the contact hole CT2 for gate.

Then, the conductor film CD mainly containing aluminum (Al) is formed in the contact holes CT1 and CT2 and on the interlayer insulating film IL by a sputtering method or the like, as illustrated in FIGS. 8 and 9.

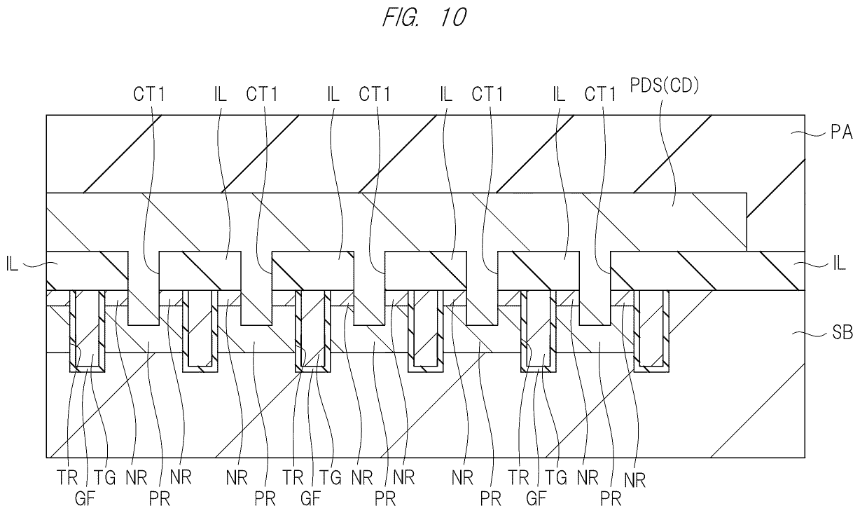

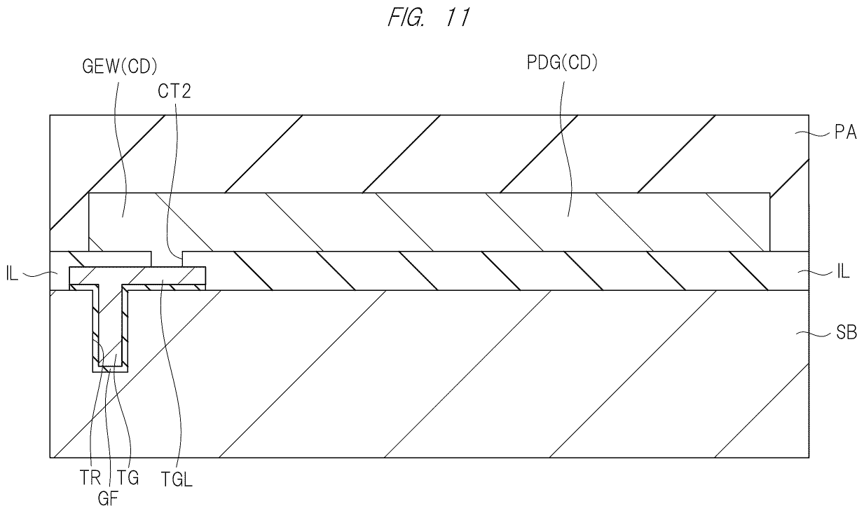

Then, the conductor film CD is patterned by photolithography technique and an etching technique, thereby forming the source pad PDS, the gate pad PDG, and the gate wiring part GEW, as illustrated in FIGS. 10 and 11. The gate pad PDG and the gate wiring part GEW are connected to each other and are integrally formed.

The source pad PDS is formed on the interlayer insulating film IL, and a part (via portion for source) of the source pad PDS fills the contact hole CT1 for source. The gate pad PDG and the gate wiring part GEW are formed on the interlayer insulating film IL, and a part (via portion for gate) of the gate wiring part GEW fills the contact hole CT2 for gate.

The via portion for source can also be formed by a step different from a step of forming the source pad PDS, and the via portion for gate can also be formed by a step different from a step of forming the gate pad PDG. In the case, a conductive plug for filling the contact holes CT1 and CT2 is formed after the step of forming the contact holes CT1 and CT2 and before the step of forming the conductor film CD.

Then, the insulating film PA is formed as a passivation film on the interlayer insulating film IL to cover the source pad PDS, the gate pad PDG, and the gate wiring part GEW, as illustrated in FIGS. 10 and 11.

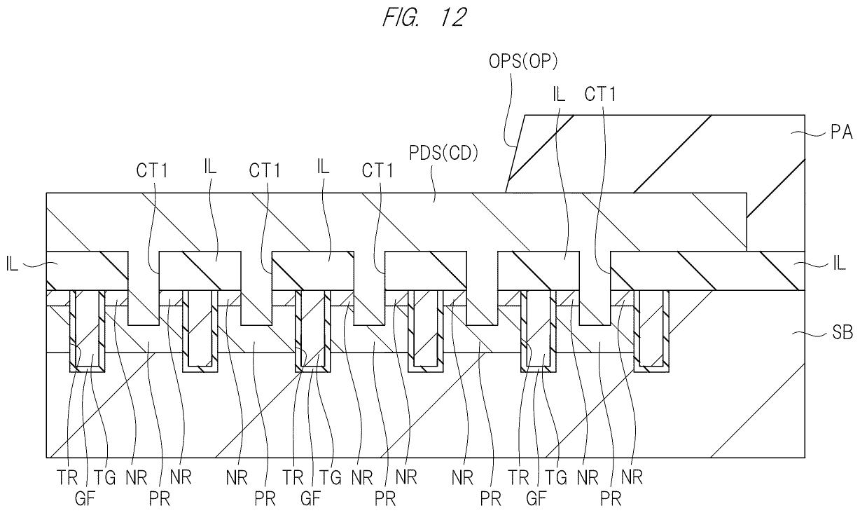

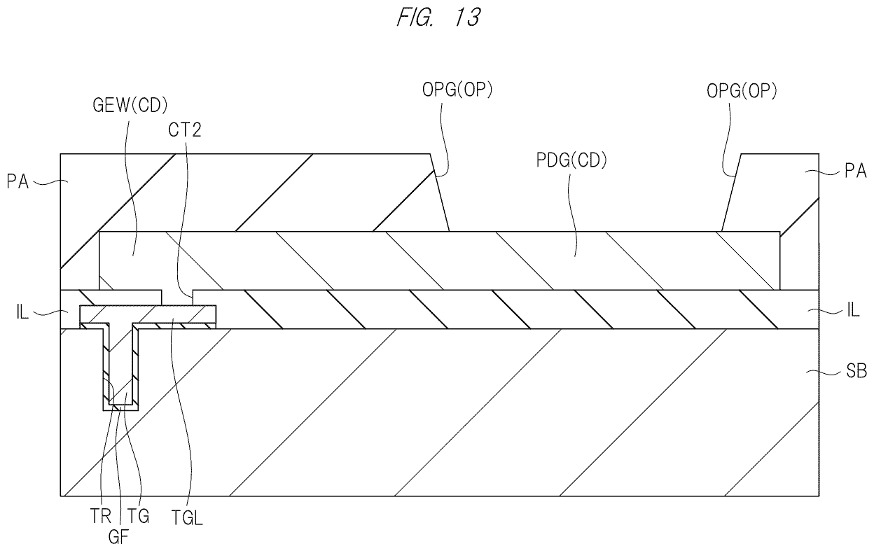

Then, the openings OPG and OPS are formed in the insulating film PA, as illustrated in FIGS. 12 and 13. For example, the openings OPG and OPS can be formed when the insulating film PA made of a photosensitive resin film is formed and is then exposed to light and developed. Alternatively, the openings OPG and OPS can be formed when the insulating film PA made of a resin film is formed and is then etched while using a photoresist pattern (not illustrated) on the insulating film PA as an etching mask.

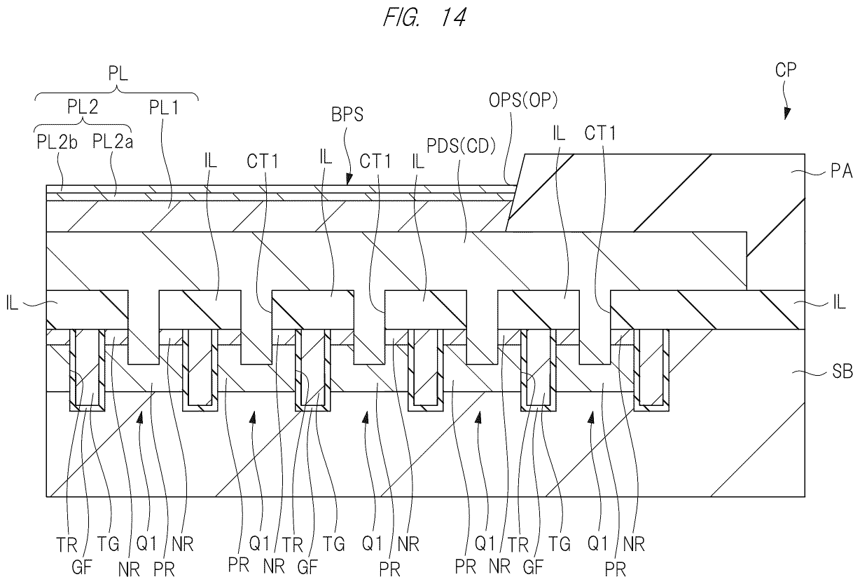

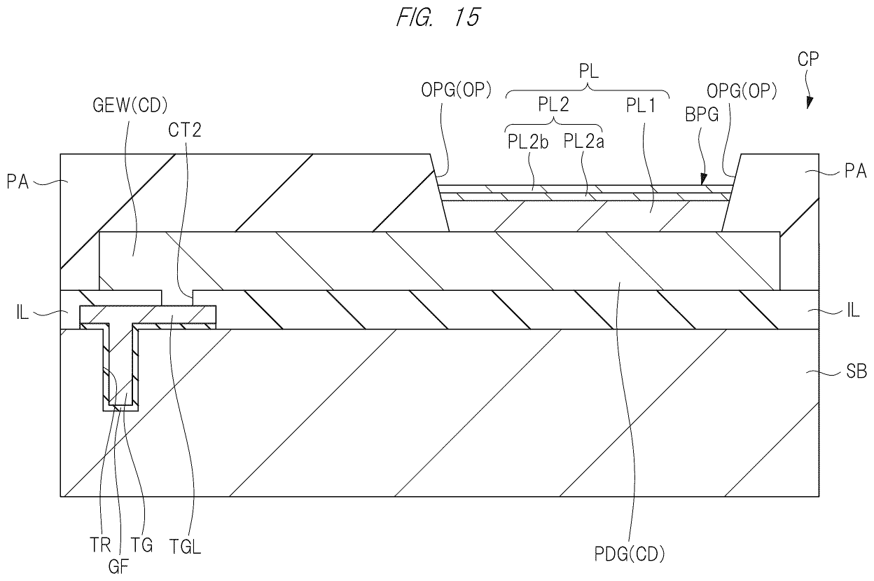

Then, the plating film PL is formed on the source pad PDS exposed from the opening OPS of the insulating film PA and the gate pad PDG exposed from the opening OPG of the insulating film PA by a plating method, as illustrated in FIGS. 14 and 15.

The plating film PL is made of a stacked film of the nickel plating film PL1, the gold plating film PL2a on the nickel plating film PL1, and the gold plating film PL2b on the gold plating film PL2a. Accordingly, a step of forming the plating film PL includes a step of forming the nickel plating film PL1, a step of forming the gold plating film PL2a, and a step of forming the gold plating film PL2b. The step of forming the gold plating film PL2a is performed after the step of forming the nickel plating film PL1, and the step of forming the gold plating film PL2b is performed after the step of forming the gold plating film PL2a. The nickel plating film PL1, the gold plating film PL2a, and the gold plating film PL2b are each formed by a plating method, specifically by an electroless plating method.

The nickel plating films PL1 are formed on the source pad PDS in the opening OPS to be in contact with the source pad PDS, and formed on the gate pad PDG in the opening OPG to be in contact with the gate pad PDG.

The nickel plating film PL1 contains phosphorus (P). Accordingly, a plating solution to be used in the step of forming the nickel plating film PL1 contains a nickel compound and a phosphorus compound. By adjustment of a composition of the plating solution to be used or the like, the phosphorus (P) concentration of the nickel plating film PL1 can be controlled. The phosphorus (P) concentration of the nickel plating film PL1 is 2% by mass or more and 7% by mass or less, preferably 2% by mass or more and 5.7% by mass or less, and more preferably 2% by mass or more and 4.0% by mass or less.

The gold plating film PL2a is formed by displacement Au (gold) plating process. In the step of forming the gold plating PL2a, a plating solution for the displacement Au plating is used. When a surface of the nickel plating film PL1 is in contact with the plating solution for the displacement Au plating, the gold plating film PL2a is formed on the surface of the nickel plating film PL1.

In the displacement Au plating process, the gold plating film PL2a is formed when gold (Au) ions in the plating solution receive electrons supplied by the displacement with nickel (Ni) contained in the nickel plating film PL1 and are deposited as a gold (Au) coating film on the surface of the nickel plating film PL1.

FIG. 16 is an explanatory diagram of a displacement reaction occurring in the displacement Au plating process. As shown in a reaction formula illustrated in FIG. 16, nickel (Ni) contained in the nickel plating film PL1 is eluted into the plating solution and becomes nickel (Ni) ions, and then, gold (Au) ions in the plating solution are chemically reduced by electrons generated by this. The chemically-reduced gold (Au) is deposited as a coating film on the nickel plating film PL1, thereby forming the gold plating film PL2a.

The gold plating film PL2b is formed by reduction Au (gold) plating process. In the step of forming the gold plating film PL2b, a plating solution for the reduction Au plating is used. When a surface of the nickel plating film PL2a is in contact with the plating solution for the reduction Au plating, the gold plating film PL2b is formed on the surface of the gold plating film PL2a.

In the reduction Au plating process, the gold plating film PL2b is formed when gold (Au) ions in the plating solution receive electrons supplied from a reducing agent in the plating solution and are deposited as a gold (Au) coating film on the surface of the nickel plating film PL2a.

Then, a back surface of the semiconductor substrate SB is ground or polished as needed to reduce the thickness of the semiconductor substrate SB.

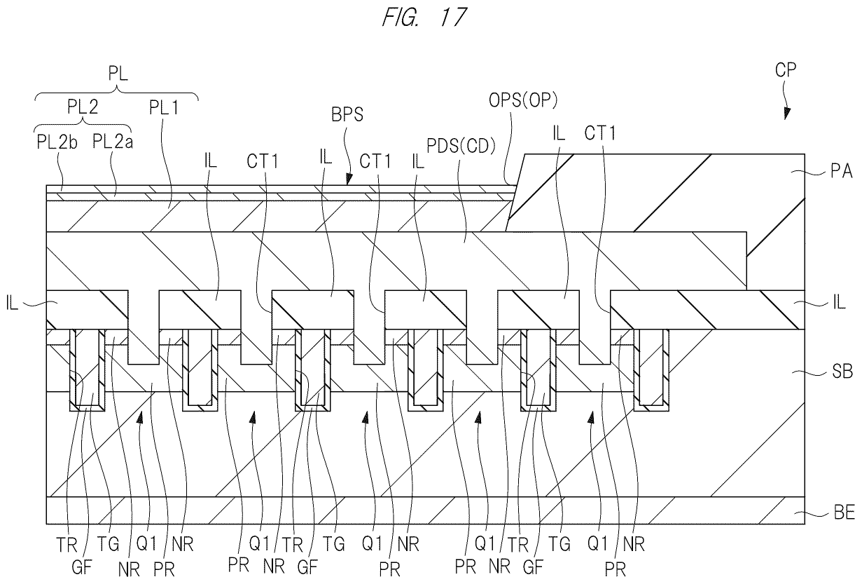

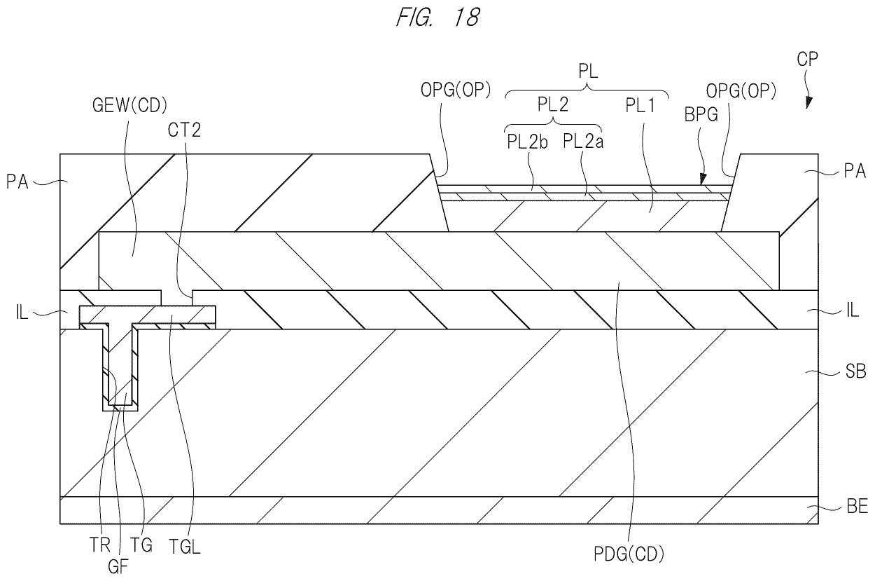

Then, the back surface electrode BE is formed on the back surface of the semiconductor substrate SB, as illustrated in FIGS. 17 and 18. The back surface electrode BE can be formed by, for example, a sputtering method.

Then, the semiconductor substrate SB is cut by dicing. Accordingly, the semiconductor device CP as a semiconductor chip can be manufactured.

### <Structure of Semiconductor Package>

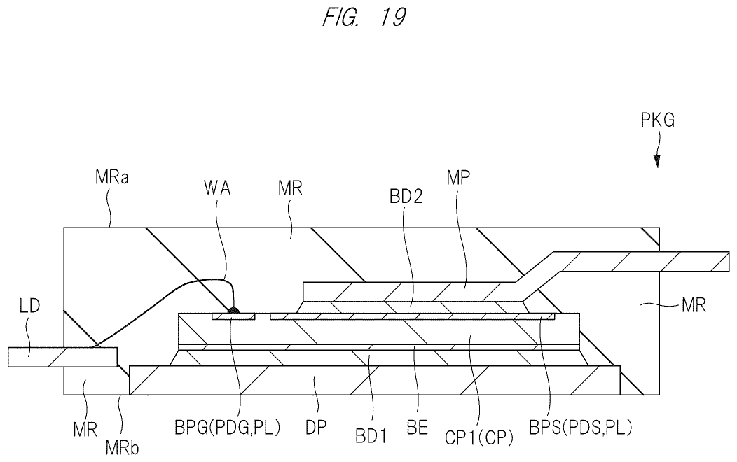

FIG. 19 is a cross-sectional view illustrating an example of a semiconductor package PKG using the semiconductor device CP.

A semiconductor chip CP1 used for the semiconductor package PKG illustrated in FIG. 19 is the same as the semiconductor device CP illustrated in FIGS. 1 to 4, and therefore, description of a configuration of the semiconductor chip CP1 is not repeated here.

As illustrated in FIG. 19, the semiconductor package PKG includes the semiconductor chip CP1, a die pad DP, a metal plate (conductor plate or clip) MP, a lead LD, a conductive wire (bonding wire) WA, and a sealing part (sealing resin part) MR.

The sealing part MR is made of a resin material such as a thermosetting resin material, and can also contain a filler or the like.

The lead LD is made of a metal material such as copper (Cu) or a copper alloy. A part (inner lead part) of the lead LD is sealed into the sealing part MR, and the other part (outer lead part) of the lead LD protrudes out of the sealing part MR from a side surface of the sealing part MR.

Although the semiconductor package PKG according to the present embodiment has a structure in which the outer lead part of the lead LD protrudes from the side surface of the sealing part MR and will be described below on the basis of this structure, the present invention is not limited to this structure. For example, the present invention can also adopt, for example, a configuration in which the lead LD hardly protrudes from the side surface of the sealing part MR while a part of the lead LD is exposed at a lower surface of the sealing part MR (a QFN-type configuration).

The semiconductor chip CP1 is mounted on an upper surface of the die pad DP. The die pad DP is a chip mounting part on which the semiconductor chip CP1 is mounted. The die pad DP is made of a metal material such as copper (Cu) or a copper alloy.

The semiconductor chip CP1 is arranged on the upper surface of the die pad DP through a conductive bonding material (die bonding material) BD1 such that the back surface electrode BE of the semiconductor chip CP1 faces the upper surface of the die pad DP through the bonding material BD1. The bonding material BD1 is made of, for example, a solder, a silver (Ag) paste, or sintered Ag (sintered silver). Accordingly, the back surface electrode BE of the semiconductor chip CP1 is electrically connected to the die pad DP through the conductive bonding material BD1. The semiconductor chip CP1 is sealed into the sealing part MR, and is not exposed from the sealing part MR.

The bonding pad for gate BPG of the semiconductor chip CP1 and the inner lead part of the lead LD are electrically connected to each other through a wire WA that is a conductive connection member. Specifically, one end of the wire WA is connected to the bonding pad for gate BPG of the semiconductor chip CP1, and the other end of the wire WA is connected to the inner lead part of the lead LD. Accordingly, the one end of the wire WA is connected to the above-described gold plating film PL2b in the uppermost layer of the bonding pad for gate BPG. The outer lead part of the lead LD functions as an external terminal electrically connected to the bonding pad for gate BPG of the semiconductor chip CP1. The wire WA is a conductive wire, and is preferably made of a metal wire such as a gold (Au) wire, a copper (Cu) wire, or an aluminum (Al) wire. The wire WA is sealed into the sealing part MR, and is not exposed from the sealing part MR.

The metal plate MP is bonded and fixed to the bonding pad for source BPS of the semiconductor chip CP1 through a conductive bonding material BD2. The bonding material BD2 is made of, for example, a solder. The metal plate MP is electrically connected to the bonding pad for source BPS of the semiconductor chip CP1 through the conductive bonding material BD2. Accordingly, the metal plate MP is connected to the above-described gold plating film PL2b in the uppermost layer of the bonding pad for source BPS through the bonding material BD2.

A part of the metal plate MP is exposed from the sealing part MR. The metal plate MP exposed from the sealing part MR functions as an external terminal electrically connected to the bonding pad for source BPS of the semiconductor chip CP1.

The metal plate MP is made of a metal material such as copper (Cu) or a copper (Cu) alloy. The metal plate MP can also be made of aluminum (Al), an aluminum (Al) alloy, silver (Ag), or a silver (A) alloy. A width of the metal plate MP is larger than a diameter of the wire WA. Accordingly, a resistance of the metal plate MP is higher than a resistance of the wire WA. The metal plate MP is connected to the bonding pad for source BPS of the semiconductor chip CP1. Accordingly, an on-resistance of a power transistor formed in the semiconductor chip CP1 can be reduced. Therefore, in the semiconductor package PKG, a conduction loss can be reduced.

The semiconductor package PKG further includes a lead for source (not illustrated), and the metal plate MP can also be electrically connected to the lead for source through a conductive bonding material. In the case, the lead for source functions as an external terminal electrically connected to the bonding pad for source BPS of the semiconductor chip CP1. In this case, the metal plate MP is not exposed from the sealing part MR.

A lower surface of the die pad DP is exposed from the lower surface of the sealing part MR. The die pad DP exposed from the lower surface of the sealing part MR functions as an external terminal electrically connected to the back surface electrode BE of the semiconductor chip CP1. Although a conduction current (on-current) of the power transistor formed in the semiconductor chip CP1 mainly flows between the metal power MP and the die pad DP, the conduction loss can be reduced because of the use of the metal plate MP for the conduction path.

Heat generated when the semiconductor chip CP1 is operated can be mainly released out of the semiconductor package PKG from the back surface of the semiconductor chip CP1 through the bonding material BD1 and the die pad DP.

### <Steps of Manufacturing Semiconductor Package>

Steps of manufacturing the semiconductor package PKG will be described.

A lead frame integrally including the die pad DP and the lead LD is prepared. In the lead frame, the die pad DP and the lead LD are each integrally connected to a frame (not illustrated) of the lead frame.

Then, a die bonding step is performed to mount the semiconductor chip CP1 on an upper surface of the die pad DP of the lead frame through the conductive bonding material BD1. Accordingly, the back surface electrode BE of the semiconductor chip CP1 is bonded to the upper surface of the die pad DP through the conductive bonding material BD1. The bonding material BD1 is a die bonding material. A solder, a silver (Ag) paste, sintered Ag (sintered silver) or the like can be used as the bonding material BD1.

The die bonding step includes a heating step. If the bonding material BD1 is the solder, the heating step is a solder reflow step. If the bonding material BD1 is the silver paste, the heating step is a heating step for curing or sintering the sliver paste.

Then, a wire bonding step is performed to connect the bonding pad for gate BPG of the semiconductor chip CP1 and the lead LD of the lead frame to each other through the wire WA. In this case, one end of the wire WA is connected to the above-described gold plating film PL2b in the uppermost layer of the bonding pad for gate BPG. Note that the wire bonding step can also be performed after a step of bonding the metal plate MP to the bonding pad for source BPS of the semiconductor chip CP1.

Then, the metal plate MP is bonded to the bonding pad for source BPS of the semiconductor chip CP1 through the conductive bonding material BD2. The metal plate MP is connected to the above-described gold plating film PL2b in the uppermost layer of the bonding pad for source BPS through the bonding material BD2.

Then, a molding step is performed to form the sealing part MR. Then, the die pad DP and the lead LD are separated from the lead frame, and the outer lead part of the lead LD is bent as needed. As a result, the semiconductor package PKG can be manufactured.

Although the case where the semiconductor package PKG includes one semiconductor chip CP1 has been described, the present invention is not limited to this. The semiconductor package PKG may include a plurality of semiconductor chips.

### <Background of Examinations>

The present inventors have examined the use of the stacked film of the nickel plating film and the gold plating film as the OPM film to be formed on the pad. The use of the stacked film of the nickel plating film and the gold plating film as the OPM film provides an advantage such as suppression of a formation cost of the OPM film more than that in use of a stacked film of a nickel plating film, a palladium plating film, and a gold plating film. The present inventors have examined the use of the bonding material (silver paste) having the high sintering temperature (about 260 degrees Celsius to 300 degrees Celsius) as the die bonding material. Accordingly, the present inventors have examined an OPM film that can endure even a heating step at a high temperature of about 300 degrees Celsius.

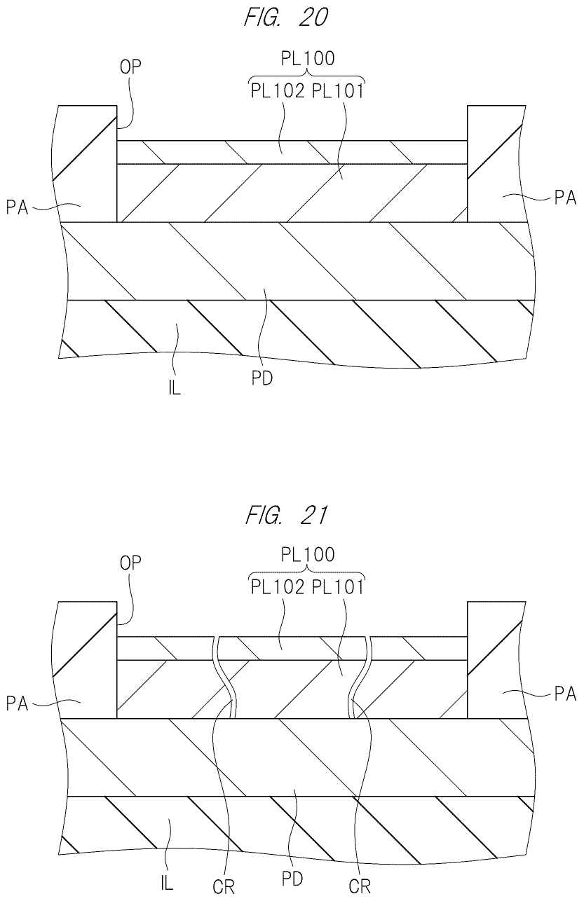

FIG. 20 is a cross-sectional view of a principal part of a semiconductor device in a first examination example examined by the present inventors.

In FIG. 20 and FIGS. 21, 22, 23, 24, 25, 28, and 29 described below, the pad (electrode pad) PD mainly containing aluminum (Al) is formed on the interlayer insulating film IL, and the insulating film (passivation film) PA is formed to cover the interlayer insulating film IL and the pad PD. An opening OP is formed in the insulating film PA to expose a part of the pad PD. The pad PD corresponds to the source pad PDS or the gate pad PDG described above, and the opening OP corresponds to the opening OPS or the opening OPG described above.

In the first examination example, an OPM film PL100 is formed on the pad PD in the opening OP of the insulating film PA, as illustrated in FIG. 20. The OPM film PL100 is made of a stacked film of a nickel plating film PL101 formed on the pad PD and a gold plating film PL102 formed on the nickel plating film PL101. The nickel plating film PL101 has a higher phosphorus concentration than that of the nickel plating film PL1 in the present embodiment. For example, the phosphorus concentration of the nickel plating film PL101 is about 9% by mass.

According to the examinations performed by the present inventors, it has been found that the first examination example has the following issues.

There is a risk that a crack occurs in the nickel plating film PL101 due to various heating steps to be performed after a step of forming the OPM film. FIG. 21 illustrates a state where a crack CR has occurred in the nickel plating film PL101 in the semiconductor device in the first examination example.

The reason why the crack CR occurs in the nickel plating film PL101 is that Ni₃P alloy is generated in the nickel plating film PL101 by heating of the nickel plating film PL101 at a high temperature, thereby embrittling the nickel plating film PL101 such that the crack CR easily occurs in the nickel plating film PL101. Types of the heating step at the high temperature causing the occurrence of the crack CR include a sputtering step of forming surface electrode BE, a heating step of increasing a bonding property between the semiconductor substrate SB and the back surface electrode BE, a die bonding step of mounting the semiconductor chip on the die pad, and a bonding step of bonding the bonding pad for source BPS and the metal plate MP under use of the solder or the like. The occurrence of the crack CR in the nickel plating film PL101 deteriorates the reliability of the semiconductor device.

### Main Features and Effects

The present inventors have examined the phosphorus concentration of the nickel plating film forming the OPM film. As a result, it has been found that the generation of the Ni₃P alloy in the nickel plating film can be suppressed or prevented by a low phosphorus concentration of the nickel plating film even if the nickel plating film is heated at a high temperature, and thus, the occurrence of the crack in the nickel plating film can be suppressed or prevented.

Accordingly, in the present embodiment, the phosphorus concentration of the nickel plating film PL1 is lowered. Specifically, the phosphorus concentration of the nickel plating film PL1 is 2% by mass or more and 7% by mass or less, preferably 2% by mass or more and 5.7% by mass or less, and more preferably 2% by mass or more and 4.0% by mass or less.

Accordingly, the generation of the Ni₃P alloy in the nickel plating film PL1 due to the various heating steps to be performed after the step of forming the OPM film can be suppressed or prevented. As a result, the occurrence of the crack in the nickel plating film PL1 can be suppressed or prevented. Therefore, the reliability of the semiconductor device can be improved.

However, according to the examinations performed by the present inventors, it has been found that the low phosphorus concentration of the nickel plating film PL1 results in formation of a low density layer (nickel low density layer) LW in the nickel plating film PL1 in the vicinity of an interface between the nickel plating film PL1 and the gold plating film on the nickel plating film PL1.

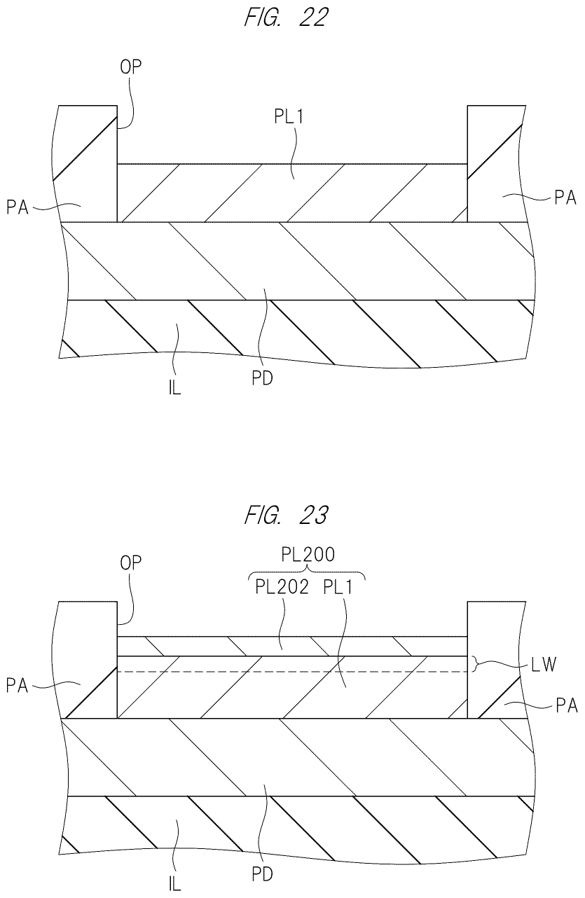

Each of FIGS. 22 and 23 is a cross-sectional view of a principal part during a step of manufacturing a semiconductor device in a second examination example examined by the present inventors. FIG. 22 illustrates a state after the nickel plating film PL1 is formed and before the gold plating film is formed on the nickel plating film PL1. FIG. 23 illustrates a state where a gold plating film PL202 is formed on the nickel plating film PL1.

In the second examination example, an OPM film PL200 is formed on the pad PD in the opening OP of the insulating film PA, as can be seen from FIGS. 22 and 23. The OPM film PL200 is made of a stacked film of the nickel plating film PL1 formed on the pad PD and the gold plating film PL202 formed on the nickel plating film PL1. The gold plating film PL202 is formed by the displacement Au plating process. In the second examination example, after the gold plating film PL202 is formed by the displacement Au plating process, the gold plating film is not formed on the gold plating film PL202 by the reduction Au plating process.

As illustrated in FIG. 23, a low density layer LW is formed in a layered form (continuously) in the nickel plating film PL1 in the vicinity of an interface between the nickel plating film PL1 and the gold plating film PL202. The density of nickel (Ni) atoms in the low density layer LW is lower than the density of nickel (Ni) atoms in the nickel plating film PL1 under the low density layer LW. The low density layer LW is not formed at a stage where the nickel plating film PL1 is formed by the nickel plating step as illustrated in FIG. 22. The low density layer LW is formed when the gold plating film is formed on the nickel plating film PL1 by the reduction Au plating process. The reason why the low density layer LW is formed is that the nickel atoms are eluted from a surface layer part of the nickel plating film PL1 into the plating solution at the time of the reduction Au plating process and become the nickel ions. Since the nickel is eluted from the surface layer part of the nickel plating film PL1 into the plating solution, the low density layer LW in which the density of the nickel atoms is low is formed in the surface layer part of the nickel plating film PL1.

The higher the phosphorus concentration of the nickel plating film is, the higher the corrosion resistance of the nickel plating film is. Accordingly, if the phosphorus concentration of the nickel plating film PL101 is high as described in the above-described first examination example, the nickel is difficult to be eluted from the nickel plating film PL101 into the plating solution at the time of the reduction Au plating process for forming the gold plating film on the nickel plating film PL101. Accordingly, if the phosphorus concentration of the nickel plating film PL101 is high as described in the first examination example, the low density layer LW is difficult to be formed in the nickel plating film PL101 in the vicinity of the interface between the nickel plating film PL101 and the gold plating film PL102.

However, if the phosphorus concentration of the nickel plating film PL1 is low as described in the present embodiment and the second examination example, the nickel is easily eluted from the nickel plating film PL1 into the plating solution at the time of the reduction Au plating process for forming the gold plating film on the nickel plating film PL1. As a result, the low density layer LW is easily formed in the surface layer part of the nickel plating film PL1.

The wire WA or the metal plate MP described above is connected to the bonding pad made of the pad PD and the OPM film. When the low density layer LW is formed in the OPM film, there is a risk of decrease in the connection strength of the wire WA or the metal plate MP. For example, there is a risk of peeling of the wire WA or the metal plate MP connected to the bonding pad due to peeling from the low density layer LW as a starting point. This results in the deterioration in the reliability of the semiconductor device. The larger the thickness of the low density layer LW is, the easier the occurrence of the peeling is. Accordingly, the thickness of the low density layer LW formed in the surface layer part of the nickel plating film PL1 is desirably suppressed at the time of the reduction Au plating process for forming the gold plating film on the nickel plating film PL1.

In order to suppress the thickness of the low density layer LW formed in the surface layer part of the nickel plating film PL, it is effective to suppress the thickness of the gold plating film formed on the nickel plating film PL1 by the reduction Au plating process. If the thickness of the gold plating film formed by the reduction Au plating process is small, an amount of the elution of the nickel from the nickel plating film PL1 into the plating solution decreases at the time of the reduction Au plating process. Accordingly, the thickness of the low density layer LW formed in the surface layer part of the nickel plating film PL1 decreases.

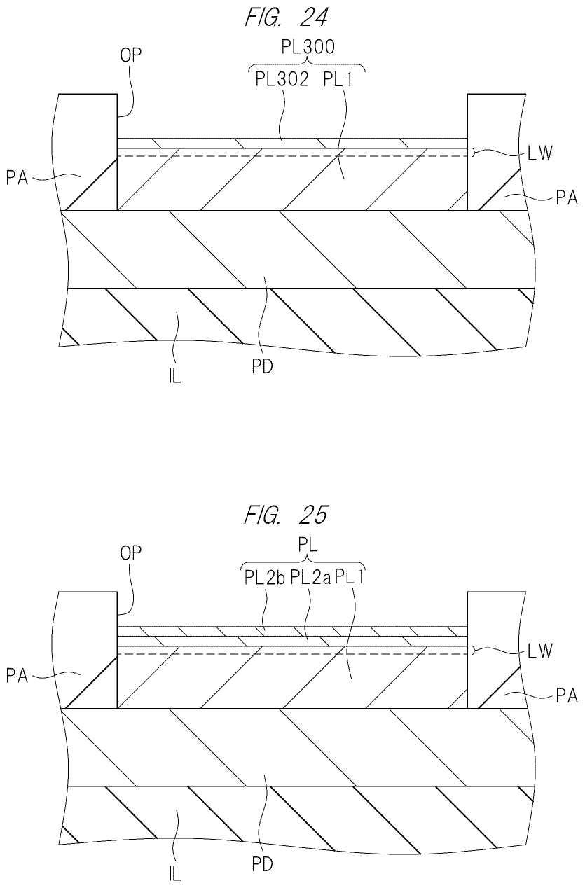

FIG. 24 is a cross-sectional view of a principal part of a semiconductor device in a third examination example examined by the present inventors.

In the third examination example, an OPM film PL300 is formed on the pad PD in the opening OP of the insulating film PA, as illustrated in FIG. 24. The OPM film PL300 is made of a stacked film of the nickel plating film PL1 formed on the pad PD and a gold plating film PL302 formed on the nickel plating film PL1. The gold plating film PL302 in the third examination example is also formed by the displacement Au plating process as similar to the gold plating film PL202 in the second examination example. However, the gold plating film PL202 in the second examination example and the gold plating film PL302 in the third examination example differ in thickness, and the thickness of the gold plating film PL302 is smaller than the thickness of the gold plating film PL202. In the third examination example, after the gold plating film PL302 is formed by the displacement Au plating process, the gold plating film is not formed, either, on the gold plating film PL302 by the reduction Au plating process, as similar to the second examination example.

In reflection of the fact that the thickness of the gold plating film PL302 in the third examination example is smaller than the thickness of the gold plating film PL202 in the second examination example, a thickness of a low density layer LW formed in the third examination example (FIG. 24) is smaller than the thickness of the low density layer LW formed in the second examination example (FIG. 23). Accordingly, in the third examination example (FIG. 24), the occurrence of the peeling from the low density layer LW as the starting point can be more suppressed than the second examination example (FIG. 23), thereby more preventing the decrease in the connection strength of the wire WA or the metal plate MP described above due to the low density layer LW.

However, in reflection of the fact that the thickness of the gold plating film PL302 in the third examination example is smaller than the thickness of the gold plating film PL202 in the second examination example, there is a risk of penetration and extrusion of the nickel (Ni) in the nickel plating film PL1 through the gold plating film PL302 to the surface of the gold plating film PL302 during various heating steps to be performed after a step of forming the OPM film PL300 in the third examination example (FIG. 24). Types of the heating step at the high temperature causing the extrusion of the nickel to the surface of the gold plating film PL302 include the sputtering step of forming the back surface electrode BE or the die bonding step of mounting the semiconductor chip on the die pad. The extrusion of the nickel to the surface of the gold plating film PL302 results in the decrease in the connection strength of the wire WA or the metal plate MP described above to the bonding pad.

Accordingly, in the second examination example (FIG. 23) in which the thick gold plating film PL202 is formed on the nickel plating film PL1, the thick low density layer LW is formed in the surface layer part of the nickel plating film PL1. Accordingly, the connection strength of the wire WA or the metal plate MP decreases. On the other hand, in the third examination example (FIG. 24) in which the thin gold plating film PL302 is formed on the nickel plating film PL1, the nickel is extruded to the front surface of the gold plating film PL302, thereby decreasing the connection strength of the wire WA or the metal plate MP. Therefore, in both the second examination example (FIG. 23) and the third examination example (FIG. 24), the connection strength of the wire WA or the metal plate MP decreases. This results in the deterioration in the reliability of the semiconductor device.

FIG. 25 is a cross-sectional view of a principal part of the semiconductor device according to the present embodiment. In the present embodiment, the low density layer LW is also formed in the layered form (continuously) in the nickel plating film PL1 in the vicinity of the interface between the nickel plating film PL1 and the gold plating film PL2a, as illustrated in FIG. 25. The density of nickel (Ni) atoms in the low density layer LW is lower than the density of nickel (Ni) atoms in the nickel plating film PL1 under the low density layer LW.

In the present embodiment, the gold plating film PL2a is formed on the nickel plating film PL1 by the displacement Au plating process, and a gold plating film PL2b is formed on the gold plating film PL2a by the reduction Au plating process. A gold plating film PL2 on the nickel plating film PL1 is made of the stacked film of the gold plating film PL2a and the gold plating film PL2b, thereby achieving the increase in the thickness of the gold plating film PL2 along with the suppression of the thickness of the gold plating film PL2a. The thickness of the low density layer LW formed in the surface layer part of the nickel plating film PL1 can be suppressed since the thickness of the gold plating film PL2a can be suppressed, while the thickness of the gold plating film PL2 can be increased since the gold plating film PL2b is formed, thereby achieving the suppression or prevention of the extrusion of the nickel to the surface of the gold plating film PL2. Accordingly, when the wire WA or the metal plate MP described above is connected to the bonding pad made of the pad PD and the plating film PL, the connection strength of the wire WA or the metal plate MP can be improved. As a result, the reliability of the semiconductor device can be improved.

For example, it is assumed that the thickness of the gold plating film PL2a in the present embodiment (FIG. 25) is the same as the thickness of the gold plating film PL302 in the third examination example while the thickness of the gold plating film PL2 in the present embodiment (FIG. 25) is the same as the thickness of the gold plating film PL202 the second examination example. In this case, the thickness of the low density layer LW formed in the surface layer part of the nickel plating film PL1 is the same between the third examination example (FIG. 24) and the present embodiment (FIG. 25). Accordingly, in the present embodiment (FIG. 25), the thickness of the low density layer LW formed in the surface layer part of the nickel plating film PL1 can be more suppressed than the second examination example (FIG. 23), and thus, the occurrence of the peeling from the low density layer LW as the starting point can be more suppressed, thereby more preventing the decrease in the connection strength of the wire WA or the metal plate MP due to the low density layer LW. In the present embodiment (FIG. 25), the total thickness of the gold plating film formed on the nickel plating film PL1 can be more increased than the third examination example (FIG. 24), and thus, the extrusion of the nickel to the front surface of the gold plating film can be more suppressed, thereby more preventing the decrease in the connection strength of the wire WA or the metal plate MP due to the extrusion of the nickel. As a result, in the present embodiment (FIG. 25), when the wire WA or the metal plate MP is connected to the bonding pad made of the pad PD and an OPM film, the connection strength of the wire WA or the metal plate MP can be more improved than the second examination example (FIG. 23) and the third examination example (FIG. 24). As a result, the reliability of the semiconductor device can be improved.

If the reduction gold plating film can be directly formed on the nickel plating film PL1 without forming the displacement gold plating film on the nickel plating film PL1, the formation of the low density layer LW in the surface layer part of the nickel plating film PL1 can be prevented. However, it is difficult to directly form the reduction gold plating film on the nickel plating film PL1.

Accordingly, the gold plating film PL2a formed to be in contact with the nickel plating film PL1 is formed by the displacement Au plating process. As a result, the gold plating film PL2a can be easily and accurately formed on the nickel plating film PL1. The gold plating film PL2b is formed on the gold plating film PL2a by the reduction Au plating process. As a result, the gold plating film PL2b can be easily and accurately formed on the gold plating film PL2a, and the thickness of the gold plating film PL2 can be increased. The gold plating film PL2b is formed to increase the entire thickness of the gold plating film PL2 without increasing the thickness of the low density layer LW. Since the gold plating film PL2b is formed on the gold plating film PL2a, the thickness of the gold plating film PL2 can be increased while the thickness of the low density layer LW is suppressed. Accordingly, the connection strength of the wire WA or the metal plate MP can be improved. As a result, the reliability of the semiconductor device can be improved.

In the present embodiment, the gold plating film PL2a is formed by the displacement Au plating process for the direct formation on the nickel plating film PL1. However, the low density layer LW is formed when the gold plating film PL2a is formed. Accordingly, it is preferable not to thicken the gold plating film PL2a. On the other hand, the gold plating film PL2b is formed for ensuring the thickness of the gold plating film PL2. Accordingly, it is preferable to thicken the gold plating film PL2b. In the present embodiment, half or more of the thickness of the gold plating film PL2 is preferably assigned to the gold plating film PL2b, and half or less of the thickness of the gold plating film PL2 is preferably assigned to the gold plating film PL2a. In other words, the thickness of the gold plating film PL2b is preferably equal to or larger than the thickness of the gold plating film PL2a. As a result, the thickness of the gold plating film PL2 can be increased while the thickness of the low density layer LW can be suppressed. Accordingly, the connection strength of the wire WA or the metal plate MP can be improved. As a result, the reliability of the semiconductor device can be improved.

The reason why the gold plating film PL2a is thinned is to thin the low density layer LW formed when the gold plating film PL2a is formed. The thinner the gold plating film PL2a is, the thinner the low density layer LW is. In order to improve the connection strength of the wire WA or the metal plate MP to the bonding pad, the thickness of the low density layer LW is preferably 20 nanometers or smaller. Accordingly, the thickness of the gold plating film PL2a is preferably set such that the thickness of the low density layer LW is 20 nanometers or smaller.

However, when the thickness of the gold plating film PL2a is too small, the gold plating film PL2b is difficult to be formed by the reduction Au plating process after the gold plating film PL2a is formed. From this viewpoint, the thickness of the gold plating film PL2a is preferably 10 nanometers or larger.

If the thickness of the gold plating film PL2 is too small, there is the risk of the passing and the extrusion of the nickel (Ni) in the nickel plating film PL1 through the gold plating film PL2 to the surface of the gold plating film PL2 during various heating steps to be performed after the step of forming the plating film PL. From this viewpoint, the thickness of the gold plating film PL2 is preferably 40 nanometers or larger. On the other hand, if the thickness of the gold plating film PL2 is too large, a time period taken for the step of forming the gold plating film PL2 is made long, and a cost for forming the gold plating film PL2 is also made high. From this viewpoint, the thickness of the gold plating film PL2 is preferably 100 nanometers or smaller.

Accordingly, although the thickness of the gold plating film PL2b is preferably equal to or larger than the thickness of the gold plating film PL2a, the thickness of the gold plating film PL2a is more preferably 10 nanometers or larger, and a total of the thickness of the gold plating film PL2a and the thickness of the gold plating film PL2b is more preferably 40 nanometers or larger and 100 nanometers or smaller. The thickness of the gold plating film PL2a is preferably about 10 nanometers or larger and 35 nanometers or smaller, although depending on the thickness of the entire gold plating film PL2.

The thickness of the nickel plating film PL1 is larger than the thickness of the gold plating film PL2, and is preferably 1 micrometer or larger and 6 micrometers or smaller.

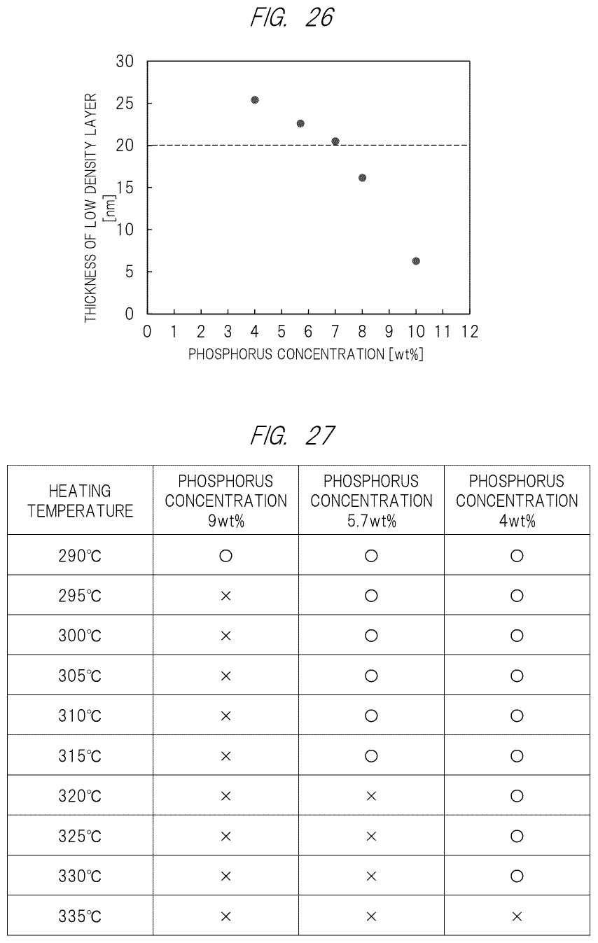

FIG. 26 is a graph illustrating a correlation between the thickness of the low density layer LW formed in the surface layer part of the nickel plating film and the phosphorus concentration of the nickel plating film in a case of formation of a displacement gold plating film having a thickness of 50 nanometers on the nickel plating film by the displacement Au plating process. The reduction gold plating film is not formed on the displacement gold plating film. A horizontal axis of the graph illustrated in FIG. 26 corresponds to the phosphorus concentration of the nickel plating film. A vertical axis of the graph illustrated in FIG. 26 corresponds to the thickness of the low density layer LW formed in the surface layer part of the nickel plating film (in the vicinity of the interface between the nickel plating film and the displacement gold plating film).

From the graph illustrated in FIG. 26, it is found that there is tendency in which the lower the phosphorus concentration of the nickel plating film is, the larger the thickness of the low density layer LW is, and the thickness of the low density layer LW exceeds 20 nanometers when the phosphorus concentration of the nickel plating film is 7% by mass or less. When the thickness of the low density layer LW exceeds 20 nanometers, the connection strength of the wire or the metal plate to the bonding pad decreases, and there is a risk of the occurrence of the peeling of the wire or the metal plate. Accordingly, the thickness of the low density layer LW is desirably set to 20 nanometers or smaller.

In the present embodiment, the gold plating film forming the OPM film is made of the stacked film of the displacement gold plating film (PL2a) and the reduction gold plating film (PL2b). Accordingly, even when the phosphorus concentration of the nickel plating film is 7% by mass or less, the thickness of the low density layer LW can be suppressed, and the thickness of the low density layer LW can be suppressed to 20 nanometers or smaller. Even when, for example, the thickness of the nickel plating film is 50 nanometers while the phosphorus concentration of the nickel plating film is 7% by mass or less, the thickness of the low density layer LW can be suppressed to 20 nanometers or smaller. Accordingly, application of the present embodiment to the case where the phosphorus concentration of the nickel plating film is 7% by mass or less provides a large effect.

FIG. 27 is a table illustrating a correlation between the phosphorus concentration of the nickel plating film and the heat resistance of the nickel plating film in the case of the use of the OPM film made of the stacked film of the nickel plating film and the gold plating film on the nickel plating film. The table of FIG. 27 illustrates results obtained by the examination on the heat resistance of the nickel plating film in respective cases where the phosphorus concentration of the nickel plating film is 9% by mass, the phosphorus concentration of the nickel plating film is 5.7% by mass, and the phosphorus concentration of the nickel plating film is 4% by mass. In the table of FIG. 27, a case where the crack has been caused in the OPM film by making contact of a needle to the OPM film when the OPM film is heated at various heating temperatures is illustrated with a cross mark, and a case where no crack has been caused in the OPM film by this is illustrated with a circle mark. By a microscopy, it has been verified whether the crack has occurred.

From the table of FIG. 27, in the case where the phosphorus concentration of the nickel plating film is 9% by mass, it is found that the occurrence of the crack in the nickel plating film can be prevented at the time of heating if the heating temperature is 290 degrees Celsius or less. In the case where the phosphorus concentration of the nickel plating film is 5.7% by mass, it is found that the occurrence of the crack in the nickel plating film can be prevented at the time of heating if the heating temperature is 315 degrees Celsius or less. In the case where the phosphorus concentration of the nickel plating film is 4% by mass, it is found that the occurrence of the crack in the nickel plating film can be prevented at the time of heating if the heating temperature is 330 degrees Celsius or less. That is, the lower the phosphorus concentration of the nickel plating film is, the more the improvement of the heat resistance of the nickel plating film is. The reason for this is that the generation of the Ni₃P alloy in the nickel plating film can be suppressed by the low phosphorus concentration of the nickel plating film even when the nickel plating film is heated at the high temperature, thereby suppressing the occurrence of the crack in the nickel plating film.

The present inventors have examined the use of the bonding material (silver paste) having the high sintering temperature (about 260 degrees Celsius to 300 degrees Celsius) as the die bonding material (bonding material BD1). Accordingly, the present inventors have examined an OPM film that can also endure heating at a high temperature of about 300 degrees Celsius. In the case where the phosphorus concentration of the nickel plating film is 5.7% by mass, no crack has occurred in the nickel plating film even in heating at a temperature of 315 degrees Celsius ensuring a 5% margin for 300 degrees Celsius that is the maximum temperature in heating. In the case where the phosphorus concentration of the nickel plating film is 4.0% by mass, no crack has occurred in the nickel plating film even in heating at a temperature of 330 degrees Celsius ensuring a 10% margin for 300 degrees Celsius that is the maximum temperature in heating. Since the heat resistance of the OPM film is improved, the occurrence of the crack is suppressed even during the sputtering step of forming the back surface electrode BE and the heating step of increasing the bonding property between the semiconductor substrate and the back surface electrode BE in addition to the die bonding step and the bonding step for the bonding pad for source, thereby improving an yield.

Accordingly, the phosphorus concentration of the nickel plating film PL1 is preferably 5.7% by mass or less, and is more preferably 4.0% by mass. As a result, the heat resistance of the nickel plating film PL1 can be improved, and the occurrence of the crack in the nickel plating film PL1 during the heating can be reliably prevented. The bonding material (silver paste) having the high sintering temperature (about 260 degrees Celsius to 300 degrees Celsius) can also be used as the die bonding material (bonding material BD1).

On the other hand, when the phosphorus concentration of the nickel plating film PL1 is too low, it is difficult to stably form the nickel plating film PL1. Accordingly, the phosphorus concentration of the nickel plating film PL1 is preferably 2% by mass or more. As a result, the nickel plating film PL1 can be easily and reliably formed.

### Second Embodiment

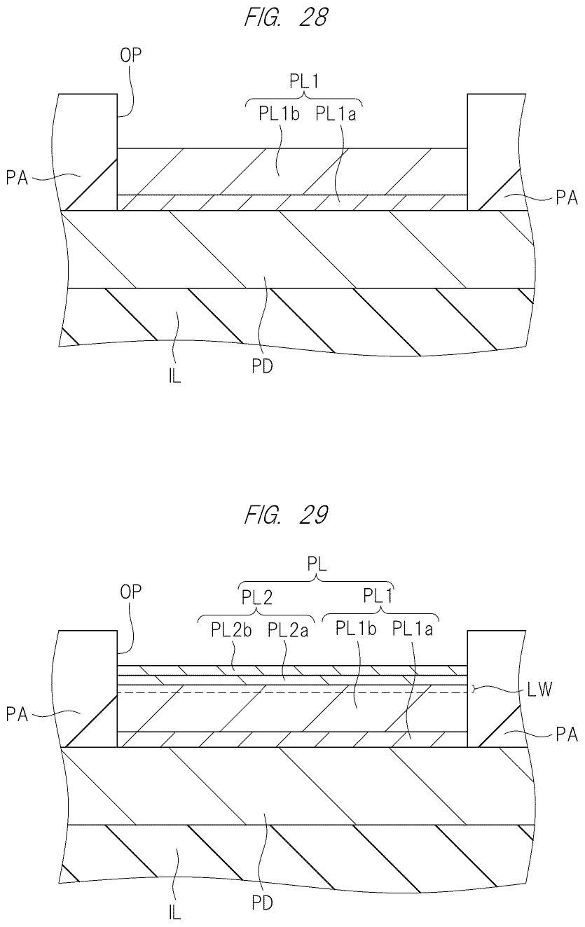

Each of FIGS. 28 and 29 is a cross-sectional view of a principal part during a step of manufacturing a semiconductor device according to a second embodiment. FIG. 28 illustrates a state after the nickel plating film PL1 is formed and before the gold plating film is formed on the nickel plating film PL1. FIG. 29 illustrates a state where the gold plating film PL2 is formed on the nickel plating film PL1.

The semiconductor device according to the second embodiment differs from the semiconductor device according to the first embodiment in the following points.

In the semiconductor device according to the present second embodiment, the nickel plating film PL1 is made of the stacked film of the nickel plating film PL1a formed on a pad PD and the nickel plating film PL1b formed on the nickel plating film PL1a in the opening OP of the insulating film PA, as illustrated in FIGS. 28 and 29. The phosphorus (P) concentration of the nickel plating film PL1a is higher than the phosphorus (P) concentration of the nickel plating film PL1b. Accordingly, a step of forming the nickel plating film PL1 in the second embodiment includes a step of forming the nickel plating film PL1a on the pad PD and a step of forming the nickel plating film PL1b on the nickel plating film PL1a after this step. The semiconductor device according to the second embodiment has a similar configuration to that of the semiconductor device according to the first embodiment except for the nickel plating film PL1.

In the second embodiment, as illustrated in FIG. 28, the nickel plating film PL1a is formed on the pad PD in the opening OP of the insulating film PA to be in contact with the pad PD. The nickel plating film PL1b is formed on the nickel plating film PL1a to be in contact with the nickel plating film PL1a. As illustrated in FIG. 29, a gold plating film PL2a is formed on the nickel plating film PL1b to be in contact with the nickel plating film PL1b by the displacement Au plating process. A gold plating film PL2b is formed on the gold plating film PL2a to be in contact with the gold plating film PL2a by the reduction Au plating process.

In the second embodiment, the low density layer LW is also formed at the time of the displacement Au plating process for forming the gold plating film PL2a, as illustrated in FIG. 29. The low density layer is LW formed in a layered form (continuously) in the nickel plating film PL1b in vicinity of an interface between the nickel plating film PL1b and the gold plating film PL2a. That is, the low density layer LW is formed in a surface layer part of the nickel plating film PL1b. The density of nickel (Ni) atoms in the low density layer LW is lower than the density of nickel (Ni) atoms in the nickel plating film PL1b under the low density layer LW.

The phosphorus concentration of each of the nickel plating films PL1a and PL1b is 2% by mass or more and 7% by mass or less, preferably 2% by mass or more and 5.7% by mass or less, and more preferably 2% by mass or more and 4.0% by mass or less. Accordingly, the generation of the Ni₃P alloy in the nickel plating film PL1 due to various heating processes to be performed after the step of forming the plating film PL can be suppressed or prevented. As a result, the occurrence of the crack in the nickel plating film PL1 can be suppressed or prevented. Therefore, the reliability of the semiconductor device can be improved.

The higher the phosphorus concentration of the nickel plating film is, the higher the corrosion resistance of the nickel plating film is. Accordingly, the corrosion resistance of the nickel plating film PL1a is higher than the corrosion resistance of the nickel plating film PL1b. The pad PD is made of the above-described conductor film CD, and thus, contains aluminum (Al) as the main component.

After the step of forming the nickel plating film PL1, water or the gold plating solution may intrude along an interface between the pad PD and the nickel plating film PL1. If the water or the gold plating solution intrude along the interface between the pad PD and the nickel plating film PL1, there is a risk of corrosion of the nickel plating film PL1 in the vicinity of the interface between the pad PD and the nickel plating film PL1. If the nickel plating film PL1 is corroded in the vicinity of the interface between the pad PD and the nickel plating film PL1, the interface between the pad PD and the nickel plating film PL1 is easily peeled. Accordingly, the reliability of the semiconductor device deteriorates. Also, there is a risk of increase in electrical resistance between the wire WA or the metal plate MP and the pad PD.

In the present embodiment, the nickel plating film PL1 is made of the stacked film of the nickel plating film PL1a and the nickel plating film PL1b on the nickel plating film PL1a, and the phosphorus concentration of the nickel plating film PL1a being in contact with the pad PD is made higher than the phosphorus concentration of the nickel plating film PL1b. The higher the phosphorus concentration of the nickel plating film is, the higher the corrosion resistance of the nickel plating film is. Accordingly, when the phosphorus concentration of the nickel plating film PL1a is made higher than the phosphorus concentration of the nickel plating film PL1b, the corrosion of the nickel plating film PL1a in the vicinity of the interface between the pad PD and the nickel plating film PL1a can be suppressed or prevented. The lower the phosphorus concentration of a nickel plating film is, the higher the heat resistance of the nickel plating film is. Accordingly, when the phosphorus concentration of the nickel plating film PL1b on the nickel plating film PL1a is made lower than the phosphorus concentration of the nickel plating film PL1a, the heat resistance of the nickel plating film PL1b can be improved. As a result, the occurrence of the crack in the nickel plating film PL1 due to various heating steps to be performed after the step of forming the plating film PL can be suppressed or prevented.

Accordingly, in the second embodiment, the corrosion of the nickel plating film PL1 in the vicinity of the interface between the pad PD and the nickel plating film PL1 and the occurrence of the crack in the nickel plating film PL1 can be suppressed or prevented. Therefore, the reliability of the semiconductor device can be further improved.

In the second embodiment, the gold plating film PL2 is also made of the stacked film of the gold plating film PL2a and the gold plating film PL2b on the gold plating film PL1a as similar to the first embodiment, thereby suppressing the thickness of the low density layer LW and increasing the thickness of the gold plating film PL2. As a result, when the wire WA or the metal plate MP described above is connected to the bonding pad made of the pad PD and the plating film PL, the connection strength of the wire WA or the metal plate MP can be improved. Therefore, the reliability of the semiconductor device can be improved.

In the foregoing, the invention made by the present inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a semiconductor substrate;
an interlayer insulating film formed on a main surface of the semiconductor substrate;
an electrode pad mainly containing aluminum formed on the interlayer insulating film;
a passivation film formed to cover the interlayer insulating film and the electrode pad;
an opening formed in the passivation film to expose a part of the electrode pad;
a nickel plating film formed on the electrode pad in the opening;
a first gold plating film formed on the nickel plating film; and
a second gold plating film formed on the first gold plating film,
wherein a phosphorus concentration of the nickel plating film is 2% by mass or more and 7% by mass or less.

2. The semiconductor device according to claim 1,
wherein the first gold plating film is a displacement gold plating film, and
wherein the second gold plating film is a reduction gold plating film.

3. The semiconductor device according to claim 1,
wherein the phosphorus concentration of the nickel plating film is 2% by mass or more and 5.7% by mass or less.

4. The semiconductor device according to claim 1,
wherein the phosphorus concentration of the nickel plating film is 2% by mass or more and 4.0% by mass or less.

5. The semiconductor device according to claim 1,
wherein a thickness of the second gold plating film is a thickness of the first gold plating film or larger.

6. The semiconductor device according to claim 5,
wherein a total of the thickness of the first gold plating film and the thickness of the second gold plating film is 40 nanometers or larger and 100 nanometers or smaller.

7. The semiconductor device according to claim 6,
wherein the thickness of the first gold plating film is 10 nanometers or larger.

8. The semiconductor device according to claim 1,
wherein a thickness of the nickel plating film is 1 micrometer or larger and 6 micrometers or smaller.

9. The semiconductor device according to claim 2,
wherein the first gold plating film is formed when Au ions receive electrons supplied by displacement with Ni and are deposited as a gold coating film on the surface of the nickel plating film.

10. The semiconductor device according to claim 2,
wherein the second gold plating film is formed by Au ions being deposited as a gold coating film on the nickel plating film upon being supplied with electrons from a reducing agent.

11. The semiconductor device according to claim 2,
wherein a nickel low density layer is formed in vicinity of an interface between the nickel plating film and the first gold plating film in the nickel plating film,
wherein a density of nickel atoms in the nickel low density layer is lower than a density of nickel atoms in the nickel plating film under the nickel low density layer, and
wherein a thickness of the nickel low density layer is 20 nanometers or smaller.

12. The semiconductor device according to claim 11,
wherein the nickel low density layer is continuously formed in the interface between the nickel plating film and the first gold plating film.

13. The semiconductor device according to claim 1,
wherein the nickel plating film is a stacked film of a first nickel plating film formed on the electrode pad and a second nickel plating film formed on the first nickel plating film, and
wherein a phosphorus concentration of the first nickel plating film is higher than a phosphorus concentration of the second nickel plating film.

14. The semiconductor device according to claim 1, further comprising
a wire or a metal plate connected to the second gold plating film.

15. The semiconductor device according to claim 1, further comprising
a semiconductor element formed on or in the semiconductor substrate,
wherein the semiconductor element is an MISFET or an IGBT.

16. A method of manufacturing a semiconductor device, comprising steps of:
(a) forming an interlayer insulating film on a main surface of a semiconductor substrate;
(b) forming an electrode pad mainly containing aluminum on the interlayer insulating film;
(c) forming a passivation film to cover the interlayer insulating film and the electrode pad;
(d) forming an opening in the passivation film to expose a part of the electrode pad;
(e) forming a nickel plating film on the electrode pad in the opening;
(f) forming a first gold plating film on the nickel plating film by displacement Au plating process; and
(g) forming a second gold plating film on the first gold plating film by reduction Au plating process,
wherein a phosphorus concentration of the nickel plating film is 2% by mass or more and 7% by mass or less.

17. The method of manufacturing the semiconductor device according to claim 16,
wherein the phosphorus concentration of the nickel plating film is 2% by mass or more and 5.7% by mass or less.

18. The method of manufacturing the semiconductor device according to claim 16,
wherein the phosphorus concentration of the nickel plating film is 2% by mass or more and 4.0% by mass or less.

19. The method of manufacturing the semiconductor device according to claim 16,
wherein a thickness of the second gold plating film formed in the step (f) is a thickness of the first gold plating film formed in the step (g) or larger.

20. The method of manufacturing the semiconductor device according to claim 16,
wherein the nickel plating film formed in the step (e) is a stacked film of a first nickel plating film formed on the electrode pad and a second nickel plating film formed on the first nickel plating film, and
wherein a phosphorus concentration of the first nickel plating film is higher than a phosphorus concentration of the second nickel plating film.
